(19) United States
(12) Patent Application Publication
(10) Pub. No.: US 2009/0008621 A1
(43) Pub. Date: Jan. 8, 2009

(54) PHASE-CHANGE MEMORY ELEMENT

(75) Inventors: Yung-Fa Lin, Hsinchu City (TW); Te-Chun Wang, Hsinchu City (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/966,584

(22) Filed: Dec. 28, 2007

(30) Foreign Application Priority Data
Jul. 5, 2007 (TW) TW96124455

(51) Int. Cl. H01L 45/00

(52) U.S. Cl. 257/3; 438/102; 257/E45.002

(57) ABSTRACT

A phase-change memory element is provided. The phase-change memory element of an embodiment of the invention comprises a phase-change material layer with a concave, and a heater with an extended part, wherein the extended part of the heater is wedged in the concave of the phase-change material layer. Specifically, the extended part of the heater has a length of 10˜5000 Å.

### BACKGROUND OF THE INVENTION

1. Field of the Invention

The invention relates to a memory element, and more particularly to a phase-change memory element and method for fabricating the same.

2. Description of the Related Art

Electronic devices use different types of memories, such as DRAM, SRAM and flash memory or a combination based on application requirements, operating speed, memory size and cost considerations of the devices. Current new developments in the memory technology field include FeRAM, MRAM and phase-change memory. Among these alternative memories, phase-change memory is most likely to be mass-produced in the near future.

Phase-change memory is targeted for applications currently utilizing flash non-volatile memory. Such applications are typically mobile devices which require low power consumption, and hence, minimal programming currents. A phase-change memory cell is designed with several goals in mind: low programming current, higher reliability (including electromigration risk), smaller cell size, and faster phase transformation speed. These requirements often set contradictory requirements on feature size, but a careful choice and arrangement of materials used for the components can often widen the tolerance.

The most straightforward way to reduce the programming current is to reduce the heating area. A benefit of this strategy is simultaneous reduction of cell size. However, reducing the area results in higher cell resistance, which increases required driving voltage. All other considerations being the same, the amount of Joule heating is conserved, meaning the operating voltage is inversely proportional to the programming current. This is clearly not desirable. Reducing heating area does not necessarily improve other performance features. Phase transformation speed requires good thermal uniformity within the active regions of the cell.

In reality, cooling becomes significant for smaller structures, and heat loss to surrounding areas becomes more important with increased surface/volume ratio. As a result, temperature uniformity is degraded. In addition, the required current density must increase as heating area is reduced. This poses an electromigration concern for reliability. Hence, it is important to not only reduce the current, but also required heating. Since the amount of Joule heating input is reduced, heat loss to surrounding areas must be reduced even further.

The heating loss is proportional to thermal conductivity of the surrounding dielectric material. As a reference, the thermal conductivity of a commonly used phase-change chalcogenide, Ge2Sb2Te5, is experimentally measured to have a range of values, averaging around a value of 0.3 W/m-K. The low thermal conductivity is due to both low electron density and vacancies in the microstructure which enhance phonon scattering. Since it is the active material, it obviously cannot serve as the surrounding dielectric.

Referring to FIG. 1, a conventional phase change memory element comprises a bottom electrode 10, a dielectric layer 11, a heater 12, and a phase change material layer 13. Applying a driving voltage, the phase change area 14 is located on the contact interface between the heater 12 and the phase change material layer 13. Since the top surface of the dielectric layer 11 is coplanar with the top surface of the heater 12 and the thermal conductivities of dielectric materials exceed 1.4 W/m-K, the heat within the phase change area 14 is apt to loss to surrounding areas via the dielectric material having low thermal conductivity.

Therefore, it is necessary to develop a phase-change memory to solve the previously described problems.

### BRIEF SUMMARY OF THE INVENTION

An exemplary embodiment a phase-change memory element comprises a phase-change material layer with a concave and a heater with an extended part, wherein the extended part of the heater is wedged in the concave of the phase-change material layer.

According to another embodiment of the invention, the phase-change memory element comprises: a bottom electrode; a dielectric layer formed on the bottom electrode; an opening passing through the dielectric layer to expose the bottom electrode; a heater formed within the opening and contacting with the bottom electrode, wherein the heater has an extended part outside of the opening; and a phase-change material layer with a concave formed on the heater, wherein the extended part of the heater is wedged in the concave of the phase-change material layer.

A method for forming a phase-change memory element is also provided, comprising: forming a dielectric layer on a bottom electrode; forming an opening passing through the dielectric layer to expose the bottom electrode; forming a heater within the opening to electrically connect to the bottom electrode, wherein the top surface of the heater is coplanar with the top surface of the dielectric layer; removing a part of the dielectric layer, wherein the top surface of the dielectric layer that is not removed is lower than the top surface of the heater to define an extended part of the heater; and forming a phase-change material layer on the heater, wherein the phase-change material layer has a concave, and the extended part of the heater is wedged in the concave of the phase-change material layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a cross section of a conventional phase-change memory element.

FIGS. 2a-2d are cross sections of a method for fabricating a phase-change memory element according to an embodiment of the invention.

FIGS. 3a-3g are cross sections of a method for fabricating a phase-change memory element according to another embodiment of the invention.

FIGS. 4a-4e are cross sections of a method for fabricating a phase-change memory element according to yet another embodiment of the invention.

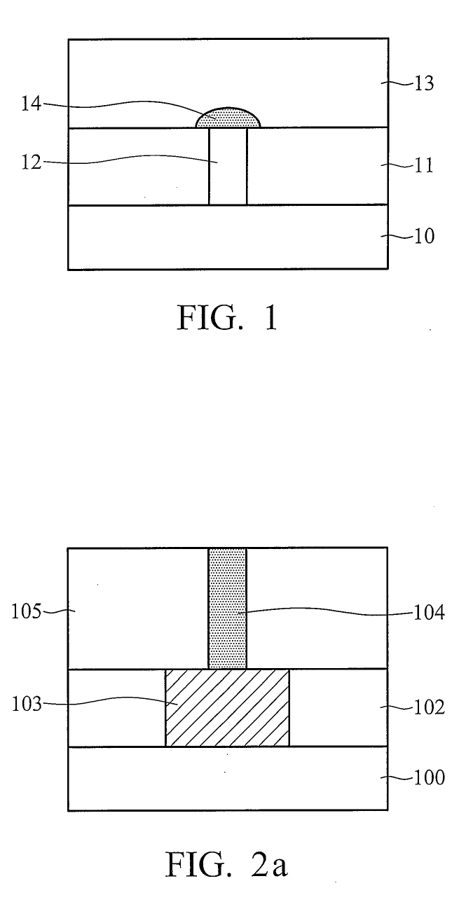

### DETAILED DESCRIPTION OF THE INVENTION

The phase-change memory element of some embodiments of the invention has a heater with an extended part surrounded by phase change material, thereby reducing heat loss to surrounding areas. Therefore, the disclosed phase-change memory element allows reduction of both programming current and programming voltage, since the required Joule heating is reduced.

The following description is of the best-contemplated mode of carrying out the invention. This description is made for the purpose of illustrating the general principles of the invention and should not be taken in a limiting sense. The scope of the invention is best determined by reference to the appended claims.

### Embodiment 1

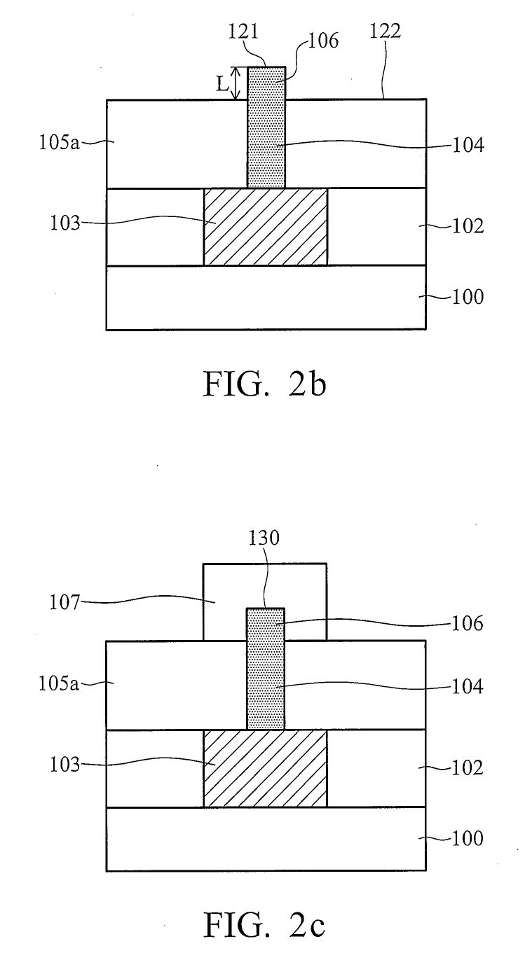

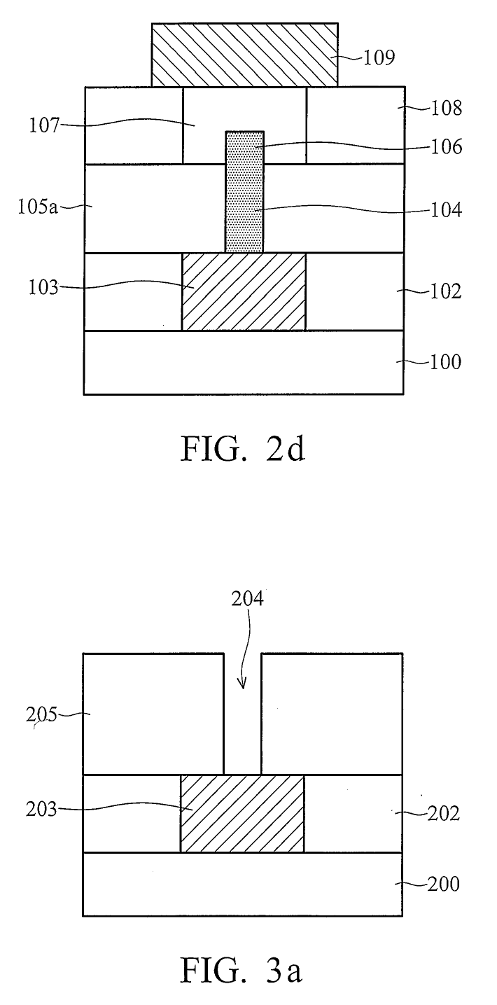

First, referring to FIG. 2a, a substrate 100 is provided, wherein a bottom electrode 103 is formed on the substrate 100. A dielectric layer 102 surrounds the bottom electrode 103, and a pillar-shaped heater 104 formed on the bottom electrode 103. A dielectric layer 105 surrounds the pillar-shaped heater 104. It should be noted that, the top surface of the dielectric layer 105 is coplanar with the top surface of the pillar-shaped heater 104.

Particularly, the substrate 100 can be a substrate employed in a semiconductor process, such as silicon substrate. The substrate 100 can be a substrate comprising a complementary metal oxide semiconductor (CMOS) circuit, isolation structure, diode, or capacitor. The accompanying drawings show the substrate 100 in a plain rectangle in order to simplify the illustration. Suitable material for the bottom electrode 103, for example, is TaN, W, TiN, or TiW. The dielectric layers 102 and 105 can be conventional dielectric material.

Next, referring to FIG. 2b, a part of the dielectric layer 105 is removed to allow the top surface 121 of the heater 104 to be higher than the top surface 122 of the dielectric layer 105a, defining a heater extended part 106. It should be noted that the dielectric layer 105a can be removed by etching process, and the dielectric layer 105 has an etching rate exceeding that of the heater 104 to leave the heater extended part 106 outside of the dielectric layer 105. In general, the etching rate of the dielectric layer 105 is 10 times larger than that of the heater 104. Furthermore, the method for removing the dielectric layer comprises chemical mechanical polishing.

Next, referring to FIG. 2c, a phase-change material layer 107 is formed on the heater 104 and the dielectric layer that was not previously removed, wherein phase-change material layer 107 has a concave 130, and the extended part 106 of the heater 104 is wedged in the concave 130 of the phase-change material layer 107. Namely, the surface of the extended part 106 completely contacts with that of the concave 130. The phase-change material layer 107 comprises chalcogenide such as In, Ge, Sb, Te or combinations thereof, for example GeSbTe or InGeSbTe.

Finally, referring to FIG. 2d, a dielectric layer 108 is formed to surround the phase-change material layer 107. Next, a top electrode 109 is formed on the phase-change material layer 107 and electrically connects to the phase-change material layer 107. The top electrode 109 can be the same as the first electrode 103 and can be metal or metal alloy, such as TaN, W, TiN, or TiW.

### Embodiment 2

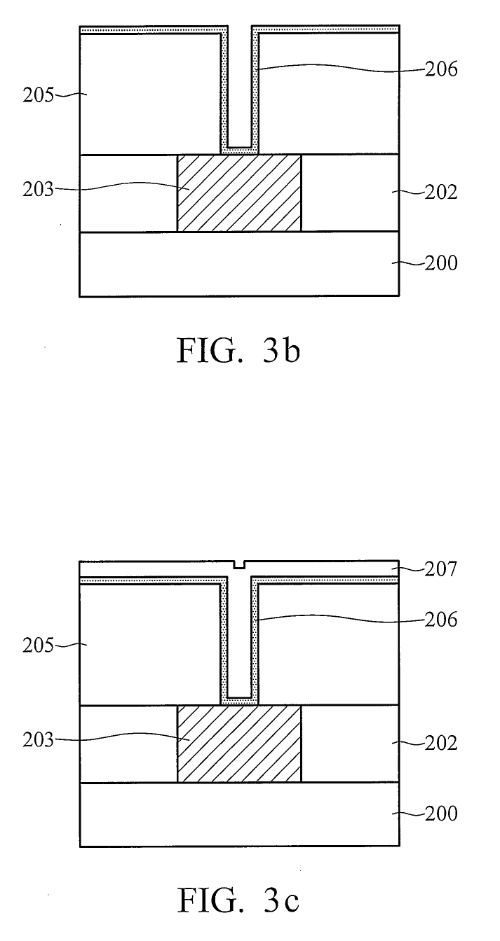

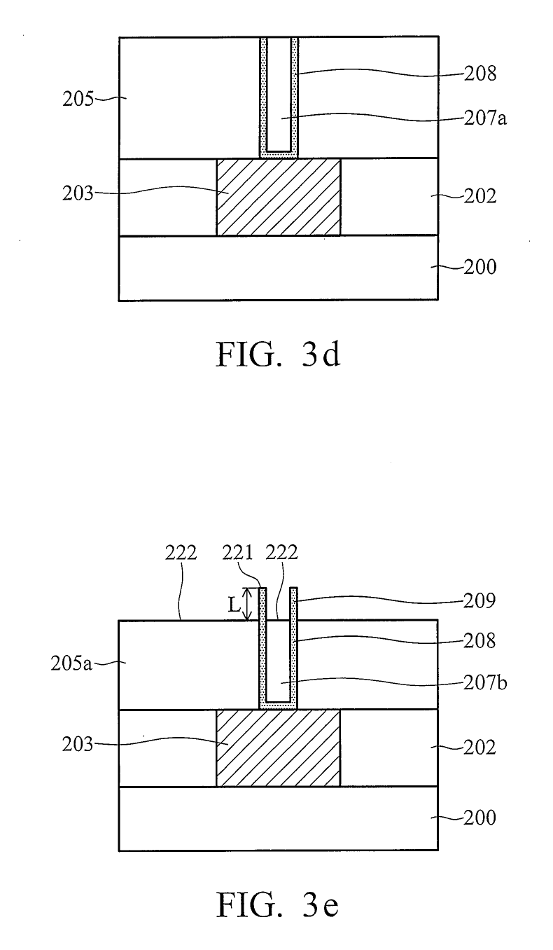

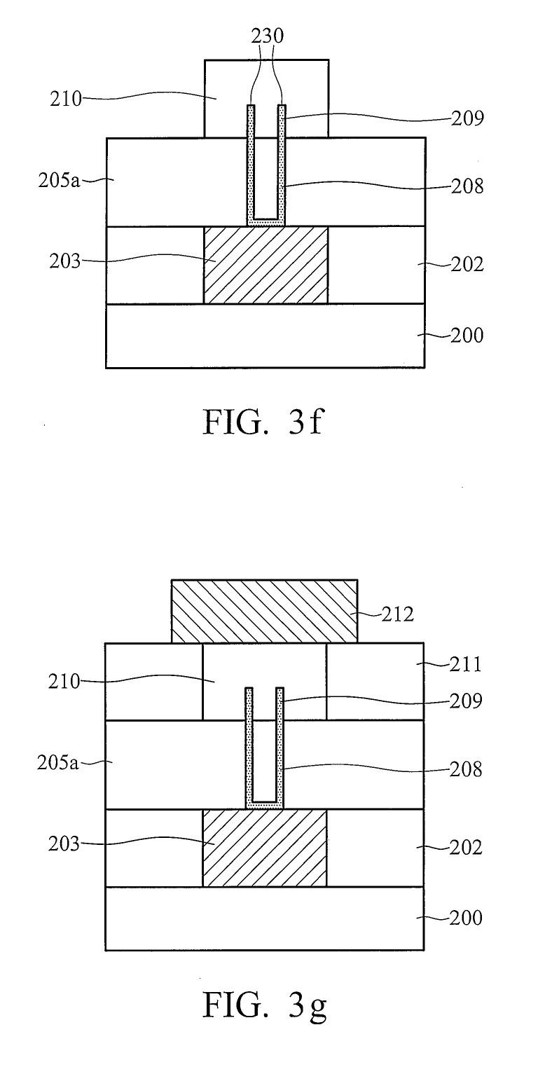

First, referring to FIG. 3a, a substrate 200 is provided, wherein a bottom electrode 203 is formed on the substrate 200. A dielectric layer 202 surrounds the bottom electrode 203.

Next, a dielectric layer 205 with an opening 204 is formed on the bottom electrode 203 and the dielectric layer 202. Particularly, the substrate 200 can be a substrate employed in a semiconductor process, such as silicon substrate. The substrate 200 can be a substrate comprising a complementary metal oxide semiconductor (CMOS) circuit, isolation structure, diode, or capacitor. The accompanying drawings show the substrate 200 in a plain rectangle in order to simplify the illustration. Suitable material for the bottom electrode 203, for example, is TaN, W, TiN, or TiW. The dielectric layers 202 and 205 can be conventional dielectric material.

Next, referring to FIG. 3b, an electrically connected layer 206 is conformally formed on the side walls and the bottom of the opening 204. Suitable material of the electrically connected layer 206 can be TaN, W, TiN, or TiW. Since the electrically connected layer 206 has a thickness of 50˜1000 Å, the dimension of the heater formed subsequently can be less than the resolution limit of a photolithography process.

Next, referring to FIG. 3c, a dielectric layer 207 is formed on the electrically connected layer 206 to fill the opening 204. Next, referring to FIG. 3d, the above structure is subjected to a planarization with the dielectric layer 205 serving as etching stopper, thus forming a cup-shaped heater 208. It should be noted that the top surface of the dielectric layer 205 is coplanar with the surface of the dielectric layer 207a and the top surface of the cup-shaped heater 208 after planarization.

Next, referring to FIG. 3e, a part of the dielectric layers 205 and 207a are removed to allow the top surface 221 of the heater 208 to be higher than the top surface 222 of the dielectric layers 205a and 207b that were not previously removed, defining a heater extended part 209. It should be noted that the dielectric layers 205a and 207b can be removed by an etching process, such a dry or wet etching. The extended part 209 can have lengths L of 10˜5000 Å, 50˜4000 Å, 100˜3000 Å, or 200˜2000 Å.

It should be noted that the top surfaces of the dielectric layers 205 and 207b must be lower than the top surface of the heater 208, and the dielectric layers 205 and 207b has an etching rate exceeding that of the heater 208 to leave the heater extended part 209 outside of the dielectric layer 205. In general, the etching rate of the dielectric layers 205 and 207b is 10 times larger than that of the heater 208.

Furthermore, the method for removing the dielectric layers comprises chemical mechanical polishing.

Next, referring to FIG. 3f, a phase-change material layer 210 is formed on the heater 208 and the dielectric layers 205a and 207b that were not previously removed, wherein the phase-change material layer 210 has a concave 230, and the extended part 209 of the heater 208 is wedged in the concave 230 of the phase-change material layer 210. Namely, the surface of the extended part 209 completely contacts with that of the concave 230. The phase-change material layer 210 comprises chalcogenide such as In, Ge, Sb, Te or combinations thereof, for example GeSbTe or InGeSbTe.

Finally, referring to FIG. 3g, a dielectric layer 211 is formed to surround the phase-change material layer 210. Next, a top electrode 212 is formed on the phase-change material layer 210 and electrically connects to the phase-change material layer 210. The top electrode 212 can be the same as the first electrode 203 and can be metal or metal alloy, such as TaN, W, TiN, or TiW.

### Embodiment 3

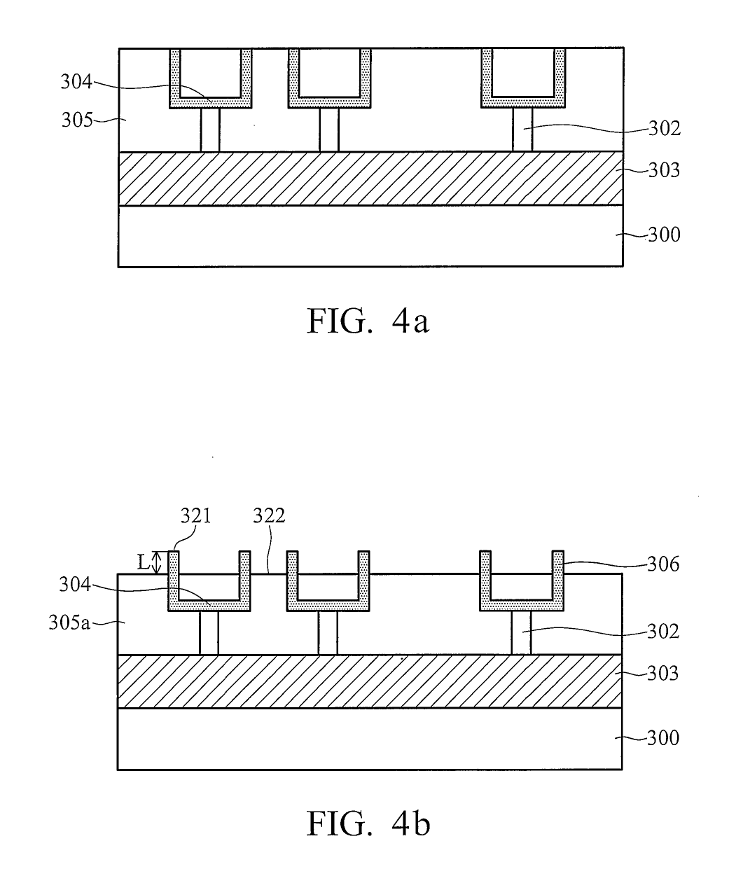

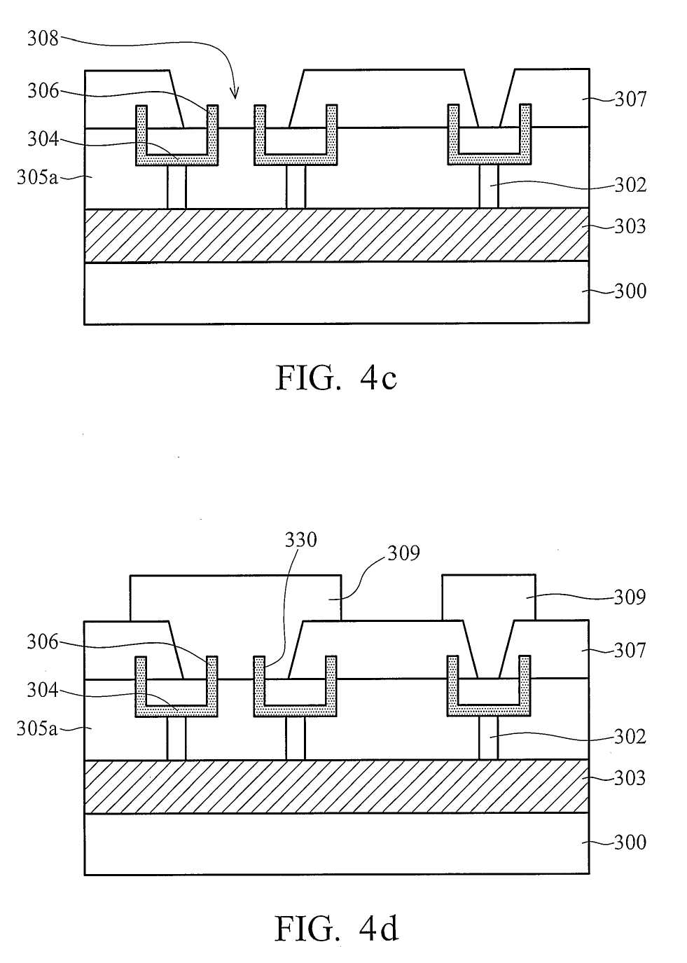

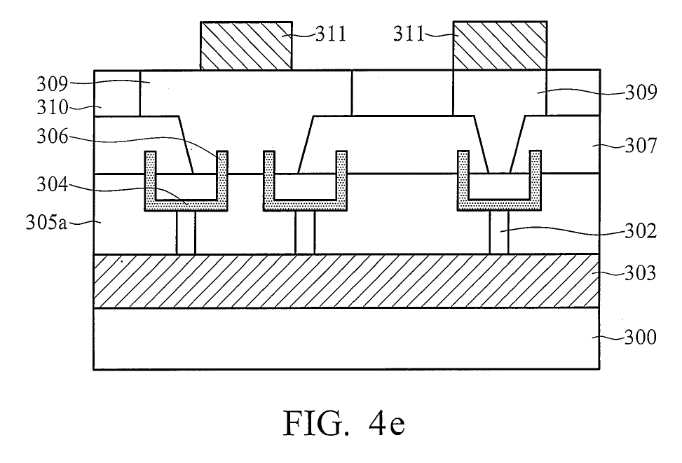

First, referring to FIG. 4a, a substrate 300 is provided, wherein a bottom electrode 303 and a plurality of cup-shaped heaters 304 is formed on the substrate 300. Each cup-shaped heater 304 electrically connects to the bottom electrode 303 via a metal plug 302. A dielectric layer 305 is formed to fill into the cup-shaped heater 304 and surround the metal plug 302. Particularly, the cup-shaped heater 304 can be formed by the method as disclosed in embodiment 2.

The substrate 300 can be a substrate comprising a complementary metal oxide semiconductor (CMOS) circuit, isolation structure, diode, or capacitor. The accompanying drawings show the substrate 300 in a plain rectangle in order to simplify the illustration. Suitable material for the bottom electrode 303, heater 304, and metal plug 302 can be the same or different and can be, for example, TaN, W, TiN, or TiW. The dielectric layers 305 can be conventional dielectric material.

Next, referring to FIG. 4b, a part of the dielectric layers 305 is removed to allow the top surface 321 of the heater 304 to be higher than the top surface 322 of the dielectric layers 305a that were not previously removed, defining a heater extended part 306. It should be noted that the dielectric layers 305 can be removed by etching process, such a dry or wet etching. The extended part 306 can have a length L of 10˜5000 Å, 50˜4000 Å, 100˜3000 Å, or 200˜2000 Å.

It should be noted that the top surfaces of the dielectric layers 305 must be lower than the top surface of the heater 304, and the dielectric layer 305 has an etching rate exceeding that of the heater 304 to leave the heater extended part 306 outside of the dielectric layer 305. In general, the etching rate of the dielectric layer 305 is 10 times larger than that of the heater 304. Furthermore, the method for removing the dielectric layers comprises chemical mechanical polishing.

Next, referring to FIG. 4c, a dielectric layer is formed on the above structure and patterned to form a patterned dielectric layer 307 and opening 308, wherein the opening 308 exposes the heater extended part 306.

Next, referring to FIG. 4d, a phase-change material layer 309 is formed on the heater 304 and the dielectric layers 305a that were not previously removed, wherein phase-change material layer 309 has a concave 330, and the extended part 306 of the heater 304 is wedged in the concave 330 of the phase-change material layer 309. Namely, the surface of the extended part 306 completely contacts with that of the concave 330. The phase-change material layer 309 comprises chalcogenide such as In, Ge, Sb, Te or combinations thereof, for example GeSbTe or InGeSbTe.

Finally, referring to FIG. 4e, a dielectric layer 310 is formed to surround the phase-change material layer 309. Next, a top electrode 311 is formed on the phase-change material layer 309 and electrically connects to the phase-change material layer 309, completing the process of the formation of μ-trench phase-change memory element. The top electrode 311 can be the same as the first electrode 203 and can be metal or metal alloy, such as TaN, W, TiN, or TiW.

Accordingly, in the embodiment of the invention, the phase-change memory element has a heater with an extended part, wherein the extended part of the heater is wedged in a concave of the phase-change material layer. Therefore, the phase-change region of the phase-change material layer is completely surrounded by the phase-change material layer, thus preventing the phase-change region from contacting (or being adjacent to) the dielectric layer (higher thermal conductivity) and heat loss to surrounding areas. Furthermore, since the extended part of the heater is completely wedged in the concave of the phase-change material layer rather simply contacting each other, the phase-change memory element of the invention has superior endurance. Since the contact area augments to a three-dimensional contact surface, the phase-change memory element has better data retention in comparison with two-dimensional contact surfaces of conventional phase-change memory elements. Moreover, the interface of the phase-change material layer and heater can be improved to increase uniformity and enhance RH/RL distribution, resulting in high stability and reappearance.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase-change memory element, comprising:
a phase-change material layer with a concave; and
a heater with an extended part, wherein the extended part of the heater is wedged in the concave of the phase-change material layer.

2. The phase-change memory element as claimed in claim 1, wherein the phase-change material layer comprises chalcogenide.

3. The phase-change memory element as claimed in claim 1, wherein the heater comprises an electrically conductive material.

4. The phase-change memory element as claimed in claim 1, wherein the heater comprises TaN, W, TiN, or TiW.

5. The phase-change memory element as claimed in claim 1, wherein the extended part of the heater has a length of 10˜5000 Å.

6. A phase-change memory element, comprising:
a bottom electrode;
a dielectric layer formed on the bottom electrode;
an opening passing through the dielectric layer to expose the bottom electrode;
a heater formed within the opening and contacting with the bottom electrode, wherein the heater has an extended part outside of the opening; and
a phase-change material layer with a concave formed on the heater, wherein the extended part of the heater is wedged in the concave of the phase-change material layer.

7. The phase-change memory element as claimed in claim 6, wherein the phase-change material layer comprises chalcogenide.

8. The phase-change memory element as claimed in claim 6, wherein the heater comprises an electrically conductive material.

9. The phase-change memory element as claimed in claim 6, wherein the heater comprises TaN, W, TiN, or TiW.

10. The phase-change memory element as claimed in claim 6, wherein the extended part of the heater has a length of 10˜5000 Å.

11. The phase-change memory element as claimed in claim 6, wherein the heater is a pillar-shaped heater.

12. The phase-change memory element as claimed in claim 6, wherein the heater is a cup-shaped heater.

13. The phase-change memory element as claimed in claim 12, wherein the method for forming the cup-shaped heater comprises the following steps:
conformally forming an electrically conductive layer; and
etching the electrically conductive layer to form the cup-shaped heater covering the side walls of the opening.

14. The phase-change memory element as claimed in claim 12, further comprising:
a metal plug, wherein the metal plug is formed between the heater and the bottom electrode, and the heater is electrically connected to the bottom electrode via the metal plug.

15. A method for forming a phase-change memory element, comprising:
forming a dielectric layer on a bottom electrode;
forming an opening passing through the dielectric layer to expose the bottom electrode;
forming a heater within the opening to electrically connect to the bottom electrode, wherein the top surface of the heater is coplanar with the top surface of the dielectric layer;
removing a part of the dielectric layer, wherein the top surface of the dielectric layer that was not previously removed is lower than the top surface of the heater to define an extended part of the heater; and
forming a phase-change material layer on the heater, wherein the phase-change material layer has a concave, and the extended part of the heater is wedged in the concave of the phase-change material layer.

16. The method as claimed in claim 15, wherein the extended part of the heater has a length of 10˜5000 Å.

17. The method as claimed in claim 15, wherein the method for removing the dielectric layer comprise an etching process.

18. The method as claimed in claim 17, wherein the dielectric layer has an etching rate exceeding that of the heater.

19. The method as claimed in claim 17, wherein a etching rate of the dielectric layer is 10 times larger than that of the heater.

20. The method as claimed in claim 17, wherein the etching process comprises a wet etching or a dry etching.

21. The method as claimed in claim 15, wherein the method for removing the dielectric layer comprise chemical mechanical polishing.

22. A method for forming a phase-change memory element, comprising:
forming a first dielectric layer on a bottom electrode;
forming an opening passing through the first dielectric layer to expose the bottom electrode;
forming a cup-shaped heater within the opening, and forming a second dielectric layer to fill the opening;
removing a part of the first and second dielectric layer, wherein the top surface of the first and second dielectric layer that is not removed is lower than the top surface of the heater to define an extended part of the heater; and
forming a phase-change material layer on the heater, wherein the phase-change material layer has a concave, and the extended part of the heater is wedged in the concave of the phase-change material layer.

23. The method as claimed in claim 22, wherein the method for forming the cup-shaped heater comprises the following steps:
conformally forming an electrically conductive layer on the first dielectric layer and the bottom electrode;
filling the second dielectric layer into the opening; and
subjecting the first and second dielectric layer and the electrically conductive layer to a polishing process, forming the cup-shaped heater.

24. The method as claimed in claim 22, wherein the extended part of the heater has a length of 10˜5000 Å.

25. The method as claimed in claim 22, wherein the method for removing the first and second dielectric layer comprise an etching process.

26. The method as claimed in claim 25, wherein the dielectric layer has an etching rate exceeding that of the heater.

27. The method as claimed in claim 25, wherein a etching rate of the dielectric layer is 10 times larger than that of the heater.

28. The method as claimed in claim 25, wherein the etching process comprises a wet etching or a dry etching.

29. The method as claimed in claim 22, wherein the method for removing the dielectric layer comprise chemical mechanical polishing.
